(19) United States
(12) Patent Application Publication
(10) Pub. No.: US 2006/0230606 A1
(43) Pub. Date: Oct. 19, 2006

(54) Methods for fabricating fuse elements

(76) Inventor: Matthew Thomas Dowil, Washington, MO (US)

Correspondence Address: John S. Beulick;Armstrong Teasdale LLP, Suite 2600, One Metropolitan Square, St. Louis, MO, 63102, US

(21) Appl. No.: 11/104,896

(22) Filed: Apr. 13, 2005

(51) Int. Cl. H01H 69/02; H05K 3/02; H01F 7/06

(52) U.S. Cl. 29/623; 29/847; 29/605

(57) ABSTRACT

A method for fabricating wire fuse elements is provided. The method includes providing a continuously extending high resistance fuse wire having a first electrical resistivity. The method also includes applying a conductive material to the wire, and reducing the first electrical resistivity of the wire to a second electrical resistivity lower than the first electrical resistivity. The method also includes selectively removing a portion of the conductive material from the wire, and forming at least one high resistance portion having the first electrical resistivity wherein the conductive material is removed, and the wire having the second electrical resistivity in portions thereof wherein the conductive material remains.

### BACKGROUND OF THE INVENTION

This invention relates generally to fuse elements, and, more particularly, to methods for fabricating wire fuse elements.

Fuses are widely used as overcurrent protection devices to prevent costly damage to electrical circuits. Fuse terminals typically form an electrical connection between an electrical power source and an electrical component or a combination of components arranged in an electrical circuit. A fusible link is connected between the fuse terminals, so that when electrical current flowing through the fuse exceeds a predetermined limit, the fusible link melts and opens the circuit through the fuse to prevent electrical component damage.

Fuse indicators have been developed for various types of fuses to facilitate identification of inoperable fuses due to an opened fuse link. Fuses including such indicators, sometimes referred to as indicating fuses, typically include a high resistivity secondary fuse link and in indicator element extending on or visible through a portion of the outer surface of an insulative fuse body. The secondary fuse link extends between conductive end caps or terminals that are attached to either end of the fuse body, and the secondary fuse link establishes a conductive path in parallel with a primary fuse link. When the primary fuse link operates to open the electrical circuit therethrough, electrical current flows through the secondary fuse link, which causes the indicator element to visibly indicate the operational state of the fuse when an operator or appropriate personnel are in the physical area or proximity of the fuses.

Wire fuse elements are widely employed to form primary and/or secondary fuse links in certain types of fuses. Typically, the wire fuse elements are fabricated from thin high resistance materials having a generally constant electrical resistivity (i.e., electrical resistance per unit length) along an axial length of the wire. In certain instances, it is desirable to provide varying resistivity in different portions of the fuse element. For example, it is sometimes desirable to provide a higher resisitivity of the fuse element in a designated portion of the fuse element to control or confine opening of the fuse element to a predetermined location or locations in the fuse element. Portions of high resistivity, sometimes referred to as weak spots, are easily formed in some types of fuse elements, such as stamped and formed fuse elements. Known methods for fabricating wire fuse elements, however, are not capable of providing varying degrees of resistivity in a wire element in a cost effective manner.

### BRIEF DESCRIPTION OF THE INVENTION

In one aspect, a method for fabricating wire fuse elements is provided. The method includes providing a continuously extending high resistance fuse wire having a first electrical resistivity. The method also includes applying a conductive material to the wire, and reducing the first electrical resistivity of the wire to a second electrical resistivity lower than the first electrical resistivity. The method also includes selectively removing a portion of the conductive material from the wire, and forming at least one high resistance portion having the first electrical resistivity wherein the conductive material is removed, and the wire having the second electrical resistivity in portions thereof wherein the conductive material remains.

In another aspect, a method for fabricating wire fuse elements is provided. The method includes providing a continuously extending high resistance fuse wire having a first electrical resistivity, the wire being overlaid with a conductive material, thereby reducing the first electrical resistivity of the wire to a second electrical resistivity lower than the first electrical resistivity. The method also includes selectively removing portions of the conductive material from the wire, thereby forming a plurality of high resistance portions having the first electrical resistivity in a plurality of portions of the wire wherein the conductive material is removed, and low resistance portions having the second electrical resistivity in portions of the wire wherein the conductive material remains.

In still another aspect, a method for fabricating wire fuse elements is provided. The method includes providing a continuously extending high resistance fuse wire having a first electrical resistivity, the wire being overlaid with a conductive material, thereby reducing the first electrical resistivity of the wire to a second electrical resistivity lower than the first electrical resistivity. The method also includes winding the overlaid wire onto a spool, and selectively removing portions of the conductive material from the wire by dipping a portion of the spool into a stripping solution such that designated portions of the overlay is removed from the wire while unaffecting other portions of the plating, thereby forming high resistance portions having the first electrical resistivity in portions of the wire wherein the conductive material is removed.

### BRIEF DESCRIPTION OF THE DRAWINGS

FIG. 1 is a schematic illustration of an exemplary indicating fuse applicable to the present invention.

FIG. 2 is a cross sectional view of an exemplary fuse state indicator applicable to the indicating fuse shown in FIG. 1.

FIG. 3 is a plan view of a wire fuse element applicable to the indicating fuse shown in FIG. 1.

FIG. 4 is a plan view of an apparatus for fabricating the fuse element shown in FIG. 3.

FIG. 5 is a side view of a stripping spool with a overlaid wire shown in FIG. 3 wound around.

FIG. 6 is a top view of the stripping spool shown in FIG. 5 with a cutting groove positioned upward.

FIG. 7 is a flow chart of an exemplary method for fabricating the wire fuse element shown in FIG. 3.

### DETAILED DESCRIPTION OF THE INVENTION

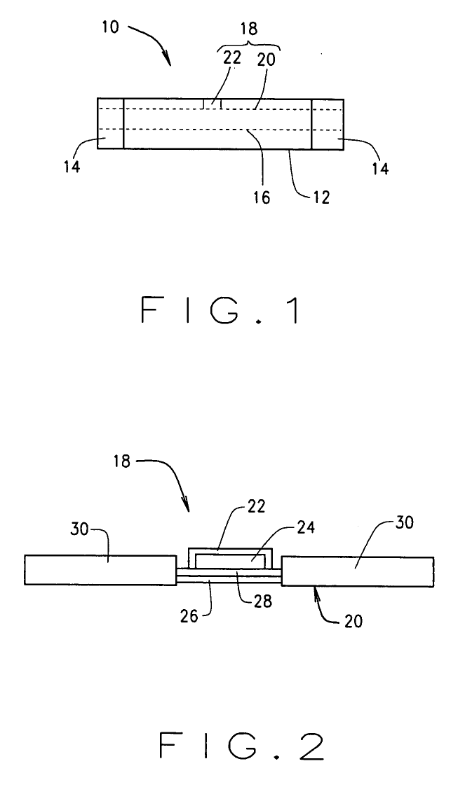

FIG. 1 is a schematic illustration of an exemplary indicating fuse 10 applicable to the present invention. The fuse 10 is a cylindrical cartridge fuse, and includes an insulative (i.e., nonconductive) fuse body 12, two conductive end caps or terminal elements 14 attached to the fuse body 12 on either end thereof, a primary fuse link 16 extending between and electrically connected to the terminal elements 14, and a fuse state indicator 18. In an exemplary embodiment, the fuse 10 is connected to line side and load side electrical circuitry (not shown) through the terminal elements 14, thereby forming a current path through the primary fuse link 16.

In an exemplary embodiment, the fuse body 12 is elongated and is generally cylindrical, and the terminal elements 14 are generally cap shaped and complementary in shape to the fuse body 12. It is appreciated, however, that other shapes and configurations of the fuse body 12 and the terminal elements 14 may be provided in alternative embodiments. Therefore, the embodiments of the fuse 10 shown and described herein are for illustrative purposes only, and the invention is not intended to be restricted to a particular fuse type, class, or rating.

In an exemplary embodiment, the primary fuse link 16 is a wire fuse element that is constructed and dimensioned to withstand only certain electrical currents flowing therethrough. Upon an occurrence of a predetermined magnitude of current corresponding to the current rating of the fuse 10, sometimes referred to as an overcurrent event, the primary fuse link 16 melts, vaporizes, disintegrates, or otherwise fails, thereby breaking the current path through the primary fuse link 16. It is appreciated, however, that the primary fuse link 16 may include more than one fuse link or element assembly in alternative embodiments.

The fuse state indicator 18 extends interior to the fuse body 12, and a portion of the fuse state indicator 18 is visible through the fuse body 12 to indicate an operating condition or state of the fuse 10 (i.e. an unopened state wherein current is conducted through the primary fuse link 16 or an opened state wherein the circuit through the primary fuse link 16 is broken). The fuse state indicator 18 includes a secondary fuse link 20 extending between and electrically connected to the terminal elements 14, thereby creating a high resistance conductive path in parallel with the primary fuse link 16. Thus, during normal operation of the fuse 10, substantially all of the current passing through the fuse 10 passes through the primary fuse link 16 due to its comparatively lower electrical resistance. When the primary fuse link 16 opens and interrupts the current path therethrough, current is diverted into the secondary fuse link 20 until the second fuse link 20 also opens to interrupt the current therethrough. The fuse state is then visibly indicated via a physical transformation of the fuse state indicator 18 when a substantial current flows through the secondary fuse link 20 when the primary fuse link 16 is opened.

FIG. 2 is a cross sectional view of an exemplary fuse state indicator 18 applicable to the indicating fuse 10 shown in FIG. 1. The fuse state indicator 18 further includes a transparent indicating lens 22 located proximate to a middle portion of the secondary fuse link 20, an indicating material 24 disposed within the indicating lens 22, and a backing layer 26 positioned behind the indicating material 24.

In an exemplary embodiment, the secondary fuse link 20 is a wire fuse element, and includes a high resistance portion 28 approximately centered in the secondary fuse link 20, and two low resistance portions 30 flanking the high resistance portion 28 for termination to the terminal elements 14 (shown in FIG. 1). The high resistivity portion 28 is sometimes referred to as a weak spot in the secondary fuse link 20. The weak spot has a reduced cross sectional area in relation to other portions of the secondary fuse link 20 so that the weak spot will be heated faster relative to other portions of the secondary fuse link 20 when current flows therethrough, and will reach the melting point or disintegration point before the remainder of the secondary fuse link 20 does. It is appreciated, however, that the secondary fuse link 20 may have more than one weak spot or high resistance portion in alternative embodiments.

In an exemplary embodiment, the indicating lens 22 is transparent and fabricated from suitable materials known in the art, including but not limited to, polycarbonate, polysulfone, polyethersulfone, and acrylic. The indicating lens 22 is visible on the fuse body 12 (shown in FIG. 1) so that by visually observing an appearance change, such as a color change through the indicating lens 22, the state of the fuse 10 (shown in FIG. 1) may be determined.

In an exemplary embodiment, the indicating material 24 is located adjacent to the high resistance portion 28, and is temperature responsive. When being heated, the indicating material 24 is physically transformed to provide fuse state indication through the indicating lens 22. In one exemplary embodiment, the indicating material 24 is a combustible material, such as nitrocellulose cotton that ignites and is consumed when being heated by the high resistance portion 28 in an overcurrent event. It is appreciated, however, that a variety of temperature responsive or heat activated materials are known in the art and could be employed as the indicating material 24 in alternative embodiments.

In an exemplary embodiment, the backing layer 26 is located adjacent and extends beyond the indicating material 24 so as to be concealed or hidden from view by the indicating material 24 when viewed through the top of the transparent indicating lens 22. The backing layer 26 is fabricated from a relatively noncombustible material relative to the indicating material 24, and is contrasting in color relative to the indicating material 24. Disposed between the indicating material 24 and the backing layer 26 is the secondary fuse link 20.

In an exemplary embodiment, the fuse state indicator 18 functions as follows. During normal operation, substantially no current flows through the secondary fuse link 20, and only the indicating material 24 is visible through the indicating lens 22. When the primary fuse link 16 (shown in FIG. 1) opens in an overcurrent event, the current flows through parallel secondary fuse link 20, which causes the secondary fuse link 20 to melt or vaporize. The resultant heat ignites the indicating material 24, and the indicating material 24 is consumed by confined burning within the indicating lens 22. When the combustion is complete, the backing layer 26 is visible through the indicating lens 22. As described above, the backing layer 26 is contrasting in color relative to the indicating material 24 so that the fuse state is readily indicated by a visible change of color from, for example, a light color to a dark color, as seen through the transparent indicating lens 22.

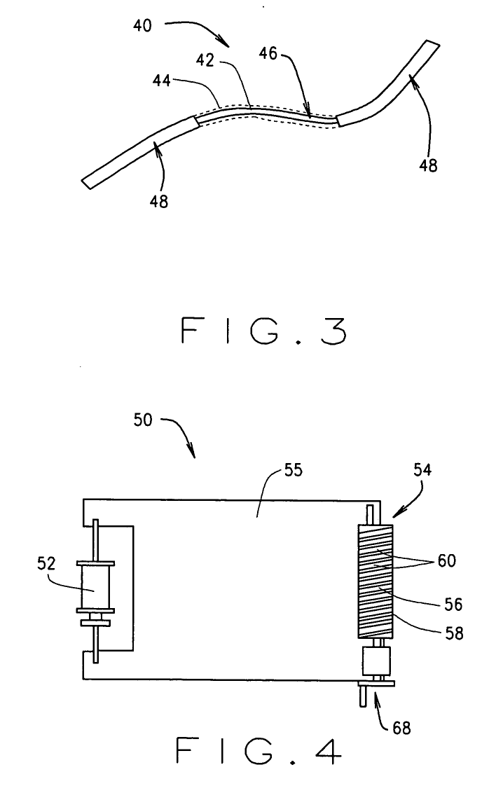

FIG. 3 is a plan view of a wire fuse element 40 applicable to the indicating fuse 10 shown in FIG. 1. In an exemplary embodiment, the fuse element 40 is fabricated from a high resistance fine fuse wire 42 that is continuously surrounded with a conductive overlay 44. The fuse wire 42 is fabricated from a first conductive material, such as silver, and has a first electrical resistivity (i.e., electrical resistance per unit length). The conductive overlay 44 is fabricated from a second conductive material, such as copper or other suitable material having a second electrical resistivity lower than the first electrical resistivity, and the conductive overlay is applied over the wire 42 with an electroplating process. It is appreciated, however, that the layer 44 may be overlaid on the fuse wire 42 by coating or other suitable methods in alternative embodiments in lieu of plating.

In an exemplary embodiment, a portion of the conductive overlay 44 is removed from the wire 42 to form a high resistance portion 46 in the fuse element 40, and the remaining portion of the conductive overlay 44 forms two low resistance portions 48 in the fuse element 40. The fuse element 40 may be employed as the primary fuse link 16 (shown in FIG. 1) or the secondary fuse link 20 (shown in FIG. 1) in the indicating fuse 10 (also shown in FIG. 1). It is appreciated, however, that the fuse element 40 may also be employed as fuse links in non-indicating fuses in alternative embodiments. In general, the location of the high resistance portion 46 within the fuse assembly determines where the fuse element 40 will most likely open and generate the greatest amount of heat in operation. By strategically locating the high resistance portion relative to other components of the fuse assembly, fuse performance in a primary fuse element, and indicating effectiveness in a secondary fuse element, may be optimized.

FIG. 4 is a plan view of an apparatus 50 for fabricating the fuse element 40 shown in FIG. 3. The apparatus 50 includes a wire roller 52, a stripping spool 54, and a base 55 rotatably supporting the wire roller 52 and the stripping spool 54 thereon. The stripping spool 54 is configured to rotate and to wind the fuse element 40 from the wire roller 52 prior to the formation of the high resistance portion 46, and is removable from the apparatus 50. The spool 54 includes a substantially cylindrical main body 56 having an outer circumferential surface 58, and a spiral groove 60 defined on the outer surface 58. The spiral groove 60 is configured to receive the wire 42 that is completely overlaid with the conductive material 44 and spirally arrange the overlaid wire around the outer surface 58 for a number of turns or revolutions about the outer surface 58.

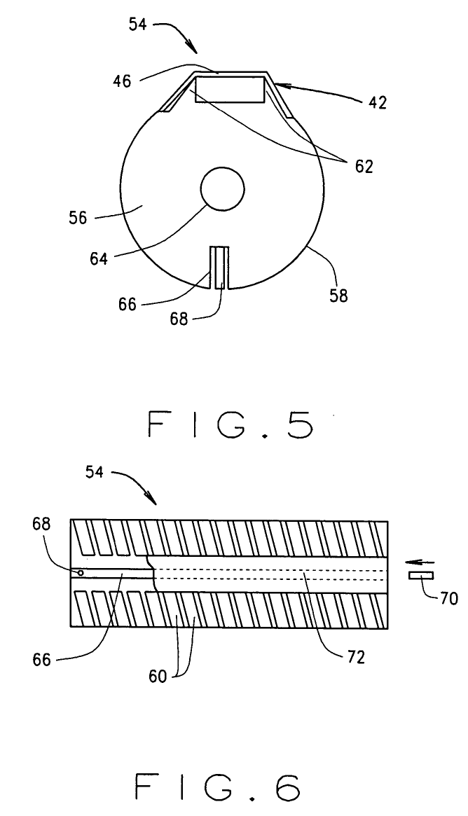

FIG. 5 is a side view of the stripping spool 54 with the overlaid wire 42 shown in FIG. 3 wound around. The spool 54 can be removed from the apparatus 50 (shown in FIG. 4) when the overlaid wire 42 is wound around the main body 56, and the spool 54 is then partially submerged into a stripping solution (not shown) for removing a portion of the conductive overlay 44 (shown in FIG. 3) from the overlaid wire 42. The spool 54 further includes two protrusions 62 extending outward from the main body 56, an axial hole 64 axially defined through the cylindrical main body 56, and a cutting groove 66 defined longitudinally across the outer surface 58.

In an exemplary embodiment, the protrusions 62 are spaced with respect to each other at a predetermined distance, and extend longitudinally along the outer surface 58. The protrusions 62 taper outward from the main body 56, and are substantially triangular in cross sectional view. The protrusions 62 are configured to space at lease one portion of the overlaid wire, that is positioned between the protrusions 62, apart from the main body 56. When the overlaid wire is spirally wound on the spool 54, a number of portions of the wire are positioned between protrusions 62 and a spaced apart from the body 56. The protrusions 62 are also configured to submerge the portion of the overlaid wire 42 positioned between the protrusions 62 into a known stripping solution or chemical bath so that the conductive overlay 44 (shown in FIG. 3) of the submerged portion is dissolved, chemically reacted, or otherwise removed from the overlaid wire 42. Thus, the high resistance portion 46 is formed on the overlaid wire 42 where the conductive overlay 44 is removed, and the low resistance portion 48 (shown in FIG. 3) is formed on the overlaid wire 42 where the conductive overlay 44 remains (i.e., portion of the overlaid wire on the spool that are not positioned between the protrusions).

The spool 54 is suspended over the pool of bath of stripping solution, and the spool 54 can be rotated to dip the wire between the protrusions 62 into the stripping solution, and also to remove the wire from the stripping solution after a predetermined time period. The conductive overlay may be stripped from the wire by submersion in the stripping solution in successive stages, or in a singe stage operation. The spool 54 further includes a handle 68 radially extending outward therefrom. The handle 68 can be manipulated to rotate the spool 54 with respect to the axis of the axial hole 64 for winding the overlaid wire 42 around the spool 54. It is appreciated, however, that the location and the structure of the handle 68 may be varied in alternative embodiments.

In an exemplary embodiment, the cutting groove 66 is longitudinally defined across the outer surface 58 at a position substantially opposite to the protrusions 62 on the spool 54. Distancing the cutting groove 66 from the protrusions 62 prevents damage to the high resistance portions 46 of the overlaid wire 42 wherein the conductive overlay is removed.

FIG. 6 is a top view of the stripping spool 54 shown in FIG. 5 with the cutting groove 66 positioned upward. In an exemplary embodiment, the cutting groove 66 is configured to receive a cutting tool 70 aligned therewith. After the high resistance portions 46 (shown in FIG. 3) are formed on the overlaid wire 42, the cutting tool 70 operates along the cutting groove 66 so that the overlaid wire 42 (shown in FIG. 3) is cut into a plurality of discrete fuse elements 40 as shown in FIG. 3, and each high resistance portion 46 is proximately centered in each fuse element 40.

In an exemplary embodiment, the spool 54 further includes an adhesive tape 72 applied thereon. The tape 72 is longitudinally applied to the main body 56 and covers the cutting groove 66, and the tape 72 adheres to the overlaid wire 42 when the overlaid wire 42 is wound around the main body 56. When the cutting tool 70 operates along the cutting groove 66, the adhesive tape 72 is cut into two halves, and each half of the tape 72 remains secured to an end of fuse elements 40 (shown in FIG. 3) cut from the spool 54, and the taped ends of the fuse element may serve to secure the fuse elements 40 in a designated location (e.g., on a surface of the fuse body 12) until the fuse 10 (FIG. 1) is assembled.

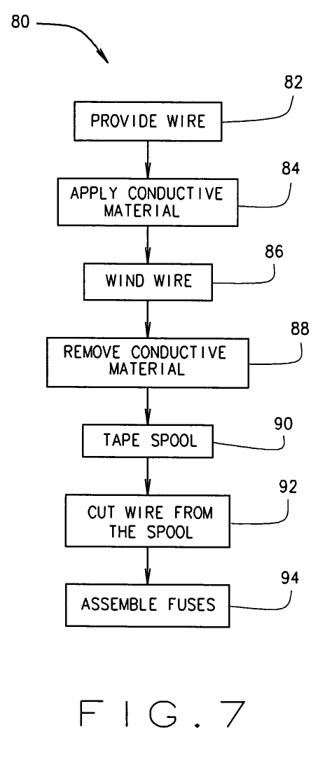

FIG. 7 is a flow chart of an exemplary method 80 for fabricating the wire fuse element 40 shown in FIG. 3. The high resistivity fuse wire 42 (shown in FIG. 3) is firstly provided 82, which is fabricated from a first conductive material, such as silver, and has a first electrical resistivity. A second conductive material, having a second electrical resistivity lower than the first electrical resistivity, is then applied 84 on the fuse wire 42, thereby reducing the electrical resistivity of the fuse wire 42 from the first electrical resistivity to the second electrical resistivity. It is appreciated that the second conductive material may be silver or other suitable material having an electrical resistivity lower than the first electrical resistivity, and the second conductive material may be applied on the fuse wire 42 by plating, coating or other suitable method.

After the second material is applied or overlaid on the fuse wire 42, the wire 42 (shown in FIG. 3) is wound 86 around the stripping spool 54 (shown in FIG. 5), and a plurality of portions of the overlaid wire 42 are spaced apart from the main body 56 (shown in FIG. 5) by the protrusions 62 (shown in FIG. 5). The spaced portions of the overlaid wire 42 are then simultaneously dipped into a stripping solution so that, the second conductive material on the dipped portions is removed 88. By removing the selected portions of the second conductive material from the wire 42, the high resistance portion 46 is formed on the wire 42 where the second conductive material is removed, and the low resistance portion 48 is formed on the wire 42 where the second conductive material remains.

After the selected portions of the second conductive material are removed, the adhesive tape 72 (shown in FIG. 6) is longitudinally applied 90 on the spool 54, and adheres to the wire 42 wound around the spool 54. Alternatively, the tape 72 may be directly applied on the spool 54 before or after the wire 42 is wound around the spool 54, and the tape 72 adheres to corresponding portions of the wire 42. The cutting tool 70 (shown in FIG. 6) then operates along the cutting groove 66 to cut 92 the wire 42 from the spool 54. The cutting tool 70 cuts the wire 42 into a plurality of discrete wire fuse elements 40 (shown in FIG. 3), and each high resistance portion 46 (shown in FIG. 3) is approximately centered in the corresponding fuse element 40. The cutting tool 70 also cuts the tape 72 into two halves, with each half of the tape 72 secured to an end of each fuse element 40, and the halves of the tape 72 are detached from the spool 54. The fuse element 40 is then ready to be assembled 94 to fuse assemblies, such as the indicating fuse 10 shown in FIG. 1.

With the apparatus and the method of the present invention, the wire fuse element can be accurately fabricated in a batch process at a low cost due to simultaneous formation of the high resistance portion on the spool of continuously wound overlaid wire, and then segmenting the wire into discrete fuse elements. The apparatus and method further provides for increased control and accuracy in defining the high resistance portion in a wire fuse element, which known wire fuse element fabrication techniques cannot accomplish.

While the invention has been described in terms of various specific embodiments, those skilled in the art will recognize that the invention can be practiced with modification within the spirit and scope of the claims.

What is claimed is:

1. A method for fabricating wire fuse elements comprising:
providing a continuously extending high resistance fuse wire having a first electrical resistivity;
applying a conductive material to the wire, thereby reducing the first electrical resistivity of the wire to a second electrical resistivity lower than the first electrical resistivity; and
selectively removing a portion of the conductive material from the wire, thereby forming at least one high resistance portion having the first electrical resistivity wherein the conductive material is removed, and the wire having the second electrical resistivity in portions thereof wherein the conductive material remains.

2. A method in accordance with claim 1 wherein said applying the conductive material comprises electroplating the conductive material to the wire.

3. A method in accordance with claim 1 wherein the fuse wire is fabricated from a first material, and said applying a conductive material to the wire comprises applying a second material different from said first material to the wire.

4. A method in accordance with claim 1 further comprising winding the wire onto a spool; and
simultaneously dipping selected portions of the wire into a stripping solution to remove the conductive material from the wire.

5. A method in accordance with claim 1 further comprising winding the wire onto a spool; and
cutting the wire into discrete fuse elements from the spool, each of the fuse elements having at least one high resistance portion.

6. A method in accordance with claim 1 wherein said cutting the wire comprises cutting the wire from the spool such that each of the fuse elements has one high resistance portion approximately centered between the ends of the fuse element.

7. A method in accordance with claim 1 further comprising taping the wire to a spool; and
cutting the wire from the spool such that a portion of the tape remains secured to the wire but not to the spool.

8. A method in accordance with claim 1 further comprising:
spirally winding the wire around a spool after the conductive material is applied, and
cutting discrete fuse elements from the spool with a cutting tool aligned axially with a longitudinal groove in the spool.

9. A method for fabricating wire fuse elements comprising:
providing a continuously extending high resistance fuse wire having a first electrical resistivity, the wire being plated with a conductive material, thereby reducing the first electrical resistivity of the wire to a second electrical resistivity lower than the first electrical resistivity; and
selectively removing portions of the conductive material from the wire, thereby forming a plurality of high resistance portions having the first electrical resistivity in a plurality of portions of the wire wherein the conductive material is removed, and low resistance portions having the second electrical resistivity in portions of the wire wherein the conductive material remains.

10. A method in accordance with claim 9 further comprising winding the wire onto a spool; and
simultaneously dipping selected portions of the wire into a stripping solution with the spool, thereby removing conductive material in the plurality of portions of the wire.

11. A method in accordance with claim 9 further comprising winding the wire onto a spool; and
cutting the wire into discrete fuse elements from the spool, each of the fuse elements having at least one high resistance portion.

12. A method in accordance with claim 11 wherein said cutting the wire comprises cutting the wire from the spool such that each of the fuse elements has one high resistance portion approximately centered between the ends of the fuse element.

13. A method in accordance with claim 9 further comprising taping the wire to a spool; and
cutting the wire from the spool such that a portion of the tape remains secured to the wire but not to the spool.

14. A method in accordance with claim 9 further comprising:
spirally winding the wire around a spool after the conductive material is applied; and
cutting discrete fuse elements from the spool with a cutting tool aligned axially with a cutting groove in the spool.

15. A method for fabricating wire fuse elements comprising:
providing a continuously extending high resistance fuse wire having a first electrical resistivity, the wire being overlaid with a conductive material, thereby reducing the first electrical resistivity of the wire to a second electrical resistivity lower than the first electrical resistivity;
winding the overlaid wire onto a spool; and
selectively removing portions of the conductive material from the wire by dipping a portion of the spool into a stripping solution such that designated portions of the overlay is removed from the wire while unaffecting other portions of the overlay, thereby forming high resistance portions having the first electrical resistivity in portions of the wire wherein the conductive material is removed.

16. A method in accordance with claim 15 wherein said winding the overlaid wire onto a spool comprises spirally winding the overlaid wire into a groove on the spool.

17. A method in accordance with claim 15 further comprising cutting the wire into discrete fuse elements from the spool, each of the fuse elements having at least one high resistance portion.

18. A method in accordance with claim 15 wherein said cutting the wire comprises cutting the wire from the spool such that each of the fuse elements has one high resistance portion approximately centered between the ends of the fuse element.

19. A method in accordance with claim 15 further comprising taping the wire to a spool; and
cutting the wire from the spool such that a portion of the tape remains secured to the wire but not to the spool.

20. A method in accordance with claim 15 further comprising cutting discrete fuse elements from the spool with a cutting tool aligned axially with a cutting groove in the spool.
